(19) United States
(12) Patent Application Publication
(10) Pub. No.: US 2006/0119494 A1
(43) Pub. Date: Jun. 8, 2006

(54) AMC (adaptive modulation and coding) method and apparatus for increasing up-link performance and record medium storing the method

(76) Inventors: Jun-Chae Na, Seoul (KR); Won-Hak Jang, Goyang-si (KR); Kyung-Tae Kim, Seoul (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/328,705

(22) Filed: Jan. 10, 2006

Related U.S. Application Data
(63) Continuation of application No. PCT/KR05/01352, filed on May 9, 2005.

(30) Foreign Application Priority Data
May 12, 2004 (KR) 10-2004-0033289

(51) Int. Cl. H03M 3/00

(52) U.S. Cl. 341/143

(57) ABSTRACT

An adaptive modulation and coding (AMC) method and apparatus for increasing up-link performance and a record medium storing the method are disclosed. In one embodiment, the method comprises: (a) receiving a signal from the base station, which stores an identical mapping table to that stored in the terminal, wherein the mapping table lists i) adaptive modulating and coding methods corresponding to plural signal-to-noise ratios (SNRs), and ii) mapping identifiers corresponding to the adaptive modulating and coding methods, (b) measuring a SNR for the received signal, (c) extracting a mapping identifier corresponding to the SNR, and (d) transmitting the mapping identifier to the base station so that the base station can demodulate and decode data received from the terminal by referring to the transmitted mapping identifier and the stored mapping table.

### RELATED APPLICATIONS

This application is a continuation application, and claims the benefit under 35 U.S.C. §§ 120 and 365 of PCT Application No. PCT/KR2005/001352, filed on May 9, 2005 and published on Nov. 17, 2005, in English, which is hereby incorporated by reference.

### BACKGROUND OF THE INVENTION

1. Field of the Invention

The present invention relates to an adaptive modulation and coding (AMC) method and apparatus for increasing up-link performance and a record medium storing the method. More particularly, the present invention relates to an AMC method and apparatus for improving capacity and efficiency of a system irrespective of any external interference by applying variable digital modulations and coding methods in the up-link portion of a wireless communication system.

2. Description of the Related Technology

An AMC method based on conventional technologies can increase transmission speed of a forward link by effectively using a system resource. In the AMC environment, mobile terminals transmit channel state information to a base station, and the base station uses different modulation and coding methods based on the received channel state information. The AMC methodology based on conventional technologies can effectively improve capacity and down-link transmission.

However, the conventional AMC methods do not improve up-link performance of a channel. Furthermore, the prior art method increases a transmission overhead because the channel state information occupies bandwidth.

Particularly, if the conventional AMC methods are used for, e.g., a radio frequency identification (RFID) system where an upward transmission is generally more frequent than a downward transmission, they significantly waste communication resources.

### SUMMARY OF CERTAIN INVENTIVE ASPECTS

One aspect of the present invention provides an AMC method, an apparatus and record medium storing the method for improving up-link performance, which can improve capacity and efficiency of a system irrespective of external interferences.

Another aspect of the present invention provides an AMC method, an apparatus and a record medium storing the method, which can not only increase capacity and up-link performance, but also improve performance and transmission rate of an up-link.

Another aspect of the present invention provides a method, an apparatus and record medium storing the method, which maintains a bit error rate (BER) required in, for example, RFID data transmission, and improves up-link data transmission rate.

Another aspect of the invention provides a method and a record medium storing the method for AMC for improving up-link performance in a terminal being in signal communication with a base station via a network, comprising: (a) receiving a signal from the base station storing an identical mapping table to that stored in the terminal, wherein the mapping table lists i) adaptive modulating and coding methods corresponding to plural signal-to-noise ratios (SNRs), and ii) information about mapping identifiers corresponding to the adaptive modulating and coding methods, (b) measuring an SNR for the received signal, (c) extracting an adaptive modulating and coding method corresponding to the SNR and an associated mapping identifier by referring to said mapping table, and (d) transmitting said mapping identifier to the base station so that the base station can demodulate and decode data received from said terminal by referring to said mapping table.

In one embodiment, the method further comprises: modulating and encoding data, to be transmitted to said base station, based on the extracted adaptive modulating and coding method, and attaching said mapping identifier with the modulated and encoded data. In one embodiment, said network is an RFID network. In one embodiment, the method further comprises: receiving said mapping table from said base station and storing the received mapping table. Another aspect of the invention provides a method for adaptive modulation and coding for improving up-link performance in a base station being in signal communication with a terminal via a network, comprising: (a) transmitting a signal to the terminal storing an identical mapping table to that stored in the base station, wherein said mapping table lists adaptive modulating and coding methods corresponding to plural SNRs, and mapping identifiers corresponding to the adaptive modulating and coding methods, (b) receiving a mapping identifier from the terminal, (c) extracting an adaptive modulating method by using said mapping identifier and said mapping table, and (d) demodulating and decoding data received from the terminal based on the extracted adaptive modulating method.

In one embodiment, said mapping identifier is received separately, or along with the data. In one embodiment, said network is an RFID network.

In one embodiment, the method further comprises: extracting said mapping table stored in the base station, and transmitting the extracted mapping table to the terminal so that the terminal can store said mapping table.

Another aspect of the invention provides a device for adaptive modulation and coding in a terminal for improving up-link performance, comprising: a receiver for receiving a signal from a base station being in signal communication with the terminal via a network, an SNR measurer for measuring SNR for the signal, a table saver for storing information of a mapping table listing i) adaptive modulating and coding methods corresponding to plural SNRs, and ii) associated mapping identifiers, an identifier extractor for extracting an adaptive modulating and coding method corresponding to the SNR and a mapping identifier corresponding to the adaptive modulating method by referring to the mapping table, a transmitter for transmitting the mapping identifier to the base station, so that the base station, which stores an identical mapping table, to said mapping table, can demodulate and decode data received from the terminal by referring to the mapping table.

In one embodiment, the device further comprises a modulator/encoder for modulating and encoding data, to be transmitted to the base station, based on the adaptive modulating and coding method, and an identifier adder for attaching the mapping identifier with the modulated and encoded data.

In one embodiment, said network is a RFID network. In one embodiment, said information of the mapping table stored in the table saver is received from the base station.

Still another aspect of the invention provides a device for adaptive modulation and coding in a base station for improving up-link performance, comprising: a transmitter for transmitting a signal to a terminal being in signal communication with the base station via a network, a receiver for receiving a mapping identifier from the terminal, wherein the mapping table is identical to the mapping table stored in the terminal, an identifier extractor for extracting the adaptive modulating method by using the mapping identifier and the mapping table, and an adaptive modulating decoder for demodulating and decoding data received from the terminal based on the extracted adaptive modulating method.

In one embodiment, said receiver receives the mapping identifier separately, or along with the data.

In one embodiment, said network is a RFID network.

### BRIEF DESCRIPTION OF THE DRAWINGS

FIG. 1 shows an adaptive modulation and coding (AMC) method according to the conventional technology.

FIG. 2 shows an AMC system network for improving performance of up-link according to one embodiment of the present invention.

FIG. 3 shows signal flows between a terminal and a base station according to one embodiment of the present invention.

FIG. 4 is a flowchart illustrating the operating procedure of the AMC method for improving performance of up-link according to one embodiment of the present invention.

FIG. 5 shows a mapping table for AMC using signal-to-noise ratio (SNR) according to one embodiment of the present invention.

FIG. 6 shows components of the terminal according to one embodiment of the present invention.

FIG. 7 is a flowchart illustrating the operation of the terminal according to one embodiment of the present invention.

FIG. 8 shows a transmitting method of the mapping identifier according to one embodiment of the present invention.

FIG. 9 shows components of the base station according to one embodiment of the present invention.

FIG. 10 is a flowchart illustrating the operation of the base station according to one embodiment of the present invention.

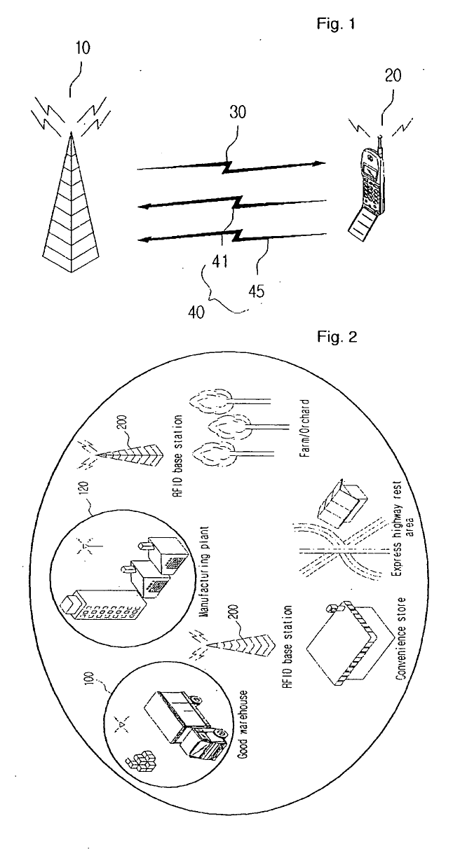

### DETAILED DESCRIPTION OF CERTAIN INVENTIVE EMBODIMENTS

Hereinafter, embodiments of the present invention will be described with accompanying drawings.

Overview of Entire System Configuration

One embodiment of the present invention eliminates a problem of overhead requiring feedbacks of additional channel state information from each terminal to the base station, and further is able to provide improved performance and increased transmission rate of up-link. FIG. 2 shows an AMC system network for improving performance of up-link according to one embodiment of the present invention.

The quality of data communication has been enhanced since the 4th generation mobile communication emerged. To compensate various channel conditions in the mobile communication system, the AMC adjusts modulating and coding techniques according to various channel conditions in a limited system, wherein the AMC is one of link adaptation techniques adjusting various transmission parameters of the transmitter.

The channel conditions are predicted by feedback of the receiver end, able to increase transmission efficiency of system, by enabling high data rate by adjusting higher code rate and higher order modulation to a user located in the good communication environment, and guaranteeing quality by adjusting lower code rate and lower order modulation to a user located in the inferior communication environment. In one embodiment, the system includes a terminal 100 in which AMC is possible and a base station 200 in which adaptive demodulation is possible.

In one embodiment, the AMC system network comprises the terminal 100 and the base station 200. Although explanation is given referring to an RFID data wireless network based on time division duplex (TDD), it is apparent that the present invention is not limited to such an embodiment.

The terminal 100 communicates data with the base station 200. In one embodiment, the terminal 100 includes a cellular phone, a PDA, a PCS and other portable communication devices. In one embodiment, the terminal 100 is an RFID reader, and referring to FIG. 2, the terminal 100 is distributed sporadically in wide area.

The base station 200 (BTS: Base Transceiver Station) allows wireless and mobile communication with each terminal 100 through a wireless access system, and transmits and receives signals to and from the BSC (Base station 200 Controller) located in the transmission path. The base station 200 can comprise a repeater for servicing to a subscriber by amplifying signals after expanding coverage area of base station 200 through optical (fiber) cable or CAI (Common Air Interface), etc at a place where service to the base station 200 is not available or location of the base station 200 is not available.

In wireless environment, it is apparent to transceiver up-link small amount of packet data rather than down-link and there is almost no mobility and multi-paths in communication.

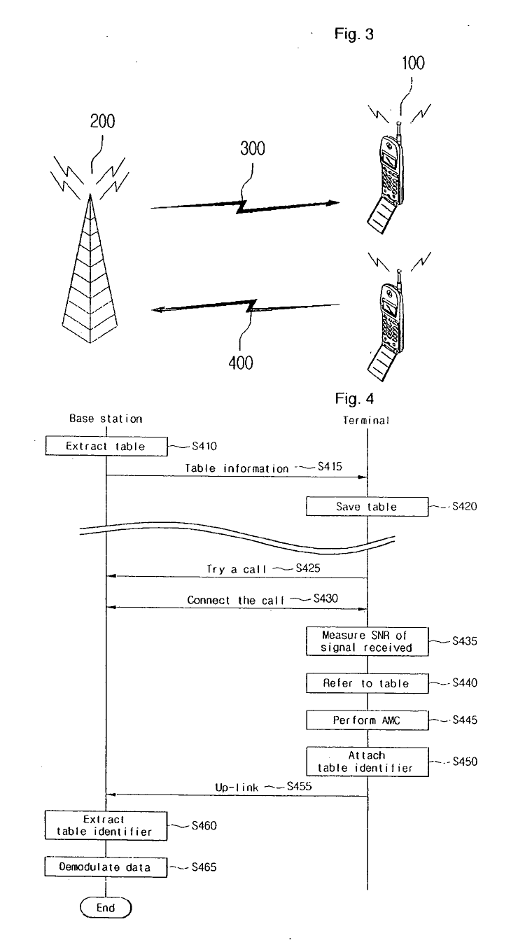

FIG. 3 shows signal flows of the terminal 100 and the base station 200 according to one embodiment of the present invention.

An AMC method based on conventional technologies is that the base station 200 receives feedback of channel state information from plural terminals 100, and then determines forward link by assigning a modulating method and a coding method corresponding to the channel state information. However, such methods consider only a communication environment for downloading of forward link. Consequently it is not effective to upload of reverse link and also overhead is created for periodically transmitting the channel state information. One embodiment of the present invention does not transmit channel state information from each terminal 100, but transmit modulating and coding identifiers so that the base station 200 can demodulate data based on the modulating and coding identifiers. Therefore, one embodiment of the present invention does not need to periodically transmit channel state information which requires a separate feedback channel.

Hereinafter, explanation will be given regarding controlling forward/reverse link according to one embodiment of the present invention by referring to FIG. 3. Here, a channel used for transmitting data from the base station 200 to the terminal 100 is named forward link or down-link, and a channel used for transmitting data from the terminal 100 to the base station 200 is named reverse link or up-link.

Wherein, information transmitted via up-link includes a mapping identifier created based on table at the terminal 100. One embodiment of the present invention can enhance the up-link speed on every data transmission method already developed or to be developed in the future. Specifically, it can enhance a transmission rate of up-link data while maintaining bit error rate (BER) requested for the system in the wireless environment such as RFID data wireless transmitting network based on TDD.

Overview of Entire System Operation

One embodiment of the present invention provides high efficiency in use of the system by employing the wireless network transmitting RFID data as described above and further to improve capacity and performance of up-link by employing simple AMC algorithm from the terminal 100 where is almost no multi-paths and mobility during communication.

FIG. 4 is a flowchart illustrating the operating procedure of an AMC method for improving performance of up-link according to one embodiment of the present invention.

While conventional AMC process of the base station 200 create considerable overhead to up-link because every terminal 100 should send feedback data of the channel state, one embodiment of the present invention can reduce or eliminate the overhead by executing the AMC based on the table by using, for example, signal-to-noise ratio (SNR) of received signals without needs of additional channel information.

Referring to FIG. 4, in step S410 the base station 200 extracts a table including coding and modulating methods according to the predetermined SNR, and then sends the table information to the terminal 100 in step S415. In step S420 the terminal 100 saves the received table information, and then identifies a modulating method and a coding method by employing a mapping identifier included in the table information in operating the AMC method.

After that, in step S425 if the terminal 100 tries a call to the base station 200, then in step S430 the call is connected to start transmitting/receiving data to/from the terminal 100. In step S435 the terminal 100 measures a value SNR of the received signal.

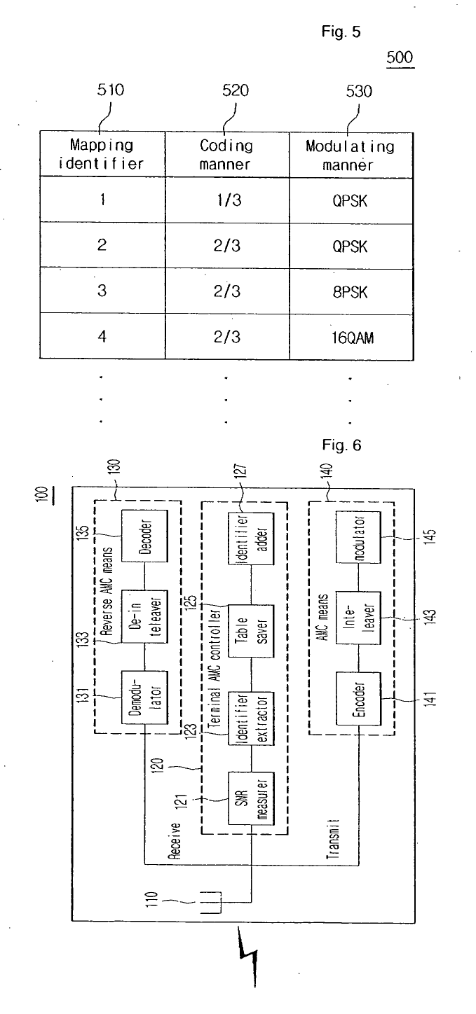

In step S440 the terminal 100 compares the table value with the SNR value measured and determines a modulating method and a coding rate of transmitted data. Here, the mapping table for AMC using signal-to-noise ratio (SNR) according to one embodiment of the present invention will be explained referring to FIG. 5. The system according to one embodiment of the present invention has almost no signal loss caused by multi-paths unlike the conventional system using AMC method at the base station 200 and uses SNR of signals received to the terminal 100 as parameters for AMC because the terminal 100 applies AMC method considering signal loss according to a distance between the terminal 100 and base station 200. The terminal 100 with high received SNR easily satisfies BER requested for the system even if the data is transmitted in high modulation and high coding rate like 640QAM because channel state is fine, while in case the terminal 100 with low received SNR, the table in FIG. 5 is set to transmit data using low modulating method and coding rate like QPSK to adjust BER requested by the system

In step S445 the terminal 100 modulates the data according to the modulating method and coding rate, attaches a mapping identifier of the table in step S450, and transmits the modulated data along with the attached mapping identifier to the base station 200 via up-link in step S455.

In step S460 the base station 200 first refers the table value included in received signal because it has an identical table with the table saved in the terminal 100, and then demodulates received information data after confirming demodulating method and the coding rate in step S465.

Because one embodiment of the present invention considers a T DD-based system, the terminal 100 can grasp SNR of received signal periodically and it is also possible to apply table-based AMC method without additional information in the terminal 100 because there is almost no mobility of the terminal 100 during data communication in the environment using RFID.

FIG. 5 shows a mapping table for AMC using signal-to-noise ratio (SNR) according to one embodiment of the present invention.

Referring to FIG. 5, the mapping table 500 comprises mapping identifiers 510, coding methods 520 and modulating methods 530.

The mapping table can be formed to correspond to a modulating method and coding rate according to the SNR value to adjust BER requested the system by transmitting much data with high modulating method and coding rate when the SNR value of the signal is high, and transmitting less data with low modulating method and coding rate when SNR value is low.

The coding method is named 1/2, 1/3, 2/3, 1/4, etc corresponding to a ratio of mixing redundancy bit, the modulating method can include QPSK, 8-PSK, 16QAM, 64QAM, etc. One embodiment of the present invention provides communication environment with SNR, the coding method and modulating method corresponding to the SNR is pre-designated.

And, it will be able to encode with low data rate like QPSK modulating method and 1/4 coding method if SNR is small (in case the signal is weak), and encode with high data rate like 64QAM and 1/2 if SNR is large (in case the signal is strong).

Although not shown in FIG. 5, in one embodiment, the mapping table can further comprise, for example, parameters for amount of error correction coding, sub-period length within the frame, number of modulation symbol from modulation symbol set, number of sub-period length of frame and the like. In one embodiment, the base station 200 can send/receive the data to/from each terminal 100 during the frame employing a function of distance between each subscriber station and the base station 200 by using at least another parameter.

Configuration and Operation of the Terminal

FIG. 6 shows components of the terminal 100 according to one embodiment of the present invention.

An AMC method based on conventional technologies is composed to feedback channel state information of the receiver end to the transmitter end, determine a form of modulation and coding method by using the channel state information, and transmit data according to the modulation and coding methods to the terminal 100. In a conventional system, the terminal 100 sends additional channel state information periodically or un-periodically to the base station 200, resulting in channel loss of reverse link due to transmitting process.

One embodiment of the present invention does not send channel state information, but increases efficiency of reverse link channel by transmitting modulation coding identification information along with the data via pre-stored mapping table.

Hereinafter, referring to FIG. 6, the terminal 100 can comprise an antenna 110, a terminal AMC controller 120, a reverse AMC means 130 and an AMC means 140.

If call is connected with the base station 200, the terminal 100 delivers a signal received from the base station 200 to the terminal AMC controller 120 through the antenna 110. In one embodiment, the terminal AMC controller 120 can comprise a SNR measurer 121 for measuring SNR of the signal, an identifier extractor 123 for determining a predetermined coding method and modulating method corresponding to the SNR and then extracting a mapping identifier for identifying the determined coding method and modulating method, a table saver 125 for saving predetermined coding methods and modulating methods corresponding to the SNR, and a identifier adder 127.

According to such determined modulating method and a coding method, the AMC means 140 is composed in order to modulate and encode data to be transmitted and the reverse AMC means 130 is composed to demodulate and decode the received data.

And the AMC means 140 can comprise a modulator 145 for modulating the data to be transmitted to the base station 200, an interleaver 143 for interleaving the modulated data and an encoder 141 for encoding the interleaved data. Here, interleaving can distribute very long burst error into plural short burst errors by differing input order and output order of data with the determined method. Namely, when the interleaved data passes a transmission channel, even very long burst error occurs, the burst error can be more corrected by performing de-interleaving at the receiver end to separate burst errors by a block than the case that interleaving is not used.

The reverse AMC means 130 can comprise a demodulator 131 for demodulating the received data from the base station 200, a de-interleaver 133 for de-interleaving the demodulated data, and a decoder 135 for decoding the de-interleaved data.

Description of other general compositions, for example a transmitter, a receiver, an input part, an output part, a power supply, etc., is omitted for convenience.

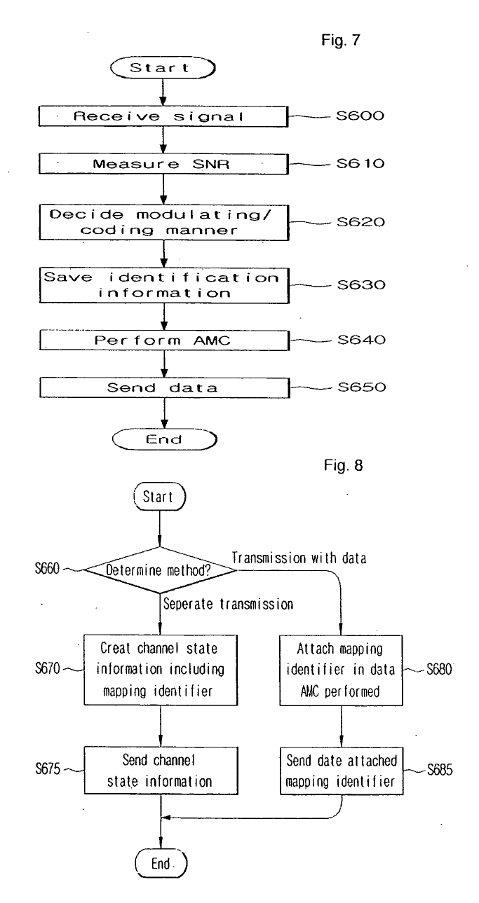

FIG. 7 is a flowchart illustrating the operation of the terminal 100 according to one embodiment of the present invention.

The terminal 100 receives a signal from the base station 200 in step S600, and then extracts the SNR of the signal in step S610.

In step S620 a modulating method and a coding method corresponding to the SNR is determined by using a mapping table. According to one embodiment, the SNR is decibel number that the signal power exceeds noise power and a ratio between the power of a signal and the power of noise since signal generally coexists with noise.

In step S630 the identification information corresponding to the modulating method and the coding method is saved, wherein the saved information can be used for modulating and decoding when the data is received from the base station 200.

In step S640 the terminal 100 can perform AMC according to the modulating method and coding method, which comprises modulation, interleaving and coding according to one embodiment.

When the terminal 100 sends the data in step S650, it transmits along with the saved table identification information and thus, it is not necessary to compose an additional feedback channel.

FIG. 8 shows a transmitting method of the mapping identifier according to one embodiment of the present invention. The transmitting method according to one embodiment of the present invention can be composed in order to send the data to the base station 200 by composing an additional feedback channel, or also can send with the mapping identifier as follows.

The transmission method of the mapping identifier is summarized in the following Table 1.

TABLE 1

| Method | Contents |
|---|---|
| Separate | Send to the base station 200 by composing an |
| transmission | additional feedback channel |
| Transmission | Send the mapping identifier along with data |
| with data | |

Hereinafter, referring to FIG. 8, the method for transmitting the mapping identifier according to one embodiment of the present invention is described. First, in step S660 a method for transmitting the mapping identifier is determined.

After determination, when the mapping identifier is transmitted along with the data, in step S670 channel state information including only the mapping identifier is generated, not including all the channel state information of the terminal 100. And in step S675 the channel state information is sent to the base station 200.

While the method for performing adaptive modulating method in the base station 200 according to conventional technologies creates considerable overhead to the up-link because the channel state of every terminal 100 should be sent as feedback data, one embodiment of the present invention can create overhead only associated with data of the mapping identifier corresponding to the table, because AMC is executed based on table by using only SNR of the received signal without requiring additional channel information. Also, since AMC is executed by using only SNR of the received signal without requiring additional channel information, only table value is associated with overhead. This is much smaller amount of feedback data compared with that for performing AMC at the base station 200.

And after determination, when the mapping identifier is transmitted separately, in step S680 the terminal 100 attaches the mapping identifier in data performed AMC according to one embodiment of the present invention, and in step S685 the data with the mapping identifier is transmitted to the base station 200.

As described above, one embodiment of the present invention can apply the AMC method based on the table at the terminal 100 by using the feature of RFID data delivery wireless network based on TDD. One embodiment of the present invention applies the AMC method according to the channel state at the terminal 100 and thus, it can improve up-link data transmission rate with maintaining bit error rate (BER) requested from the system. Further, since the AMC is performed by using only SNR of the received signal without needs of additional channel information, only table value is associated with overhead. Thus, this is a much smaller amount of feedback data compared with that for performing AMC at the base station 200.

Especially, when the mapping identifier is transmitted along with the data, it can remove occupancy rate used in transmitting channel state information from the feedback channel.

Configuration and Operation of the Base station

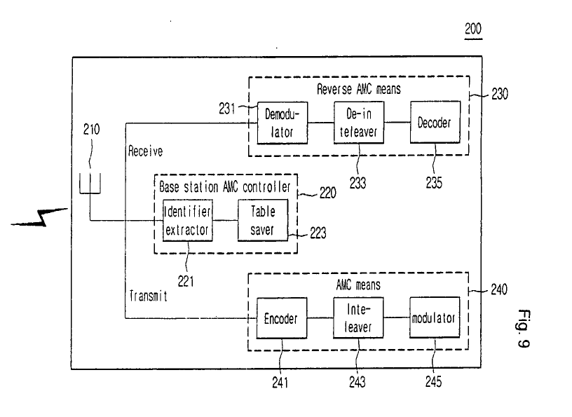

FIG. 9 shows a system of the base station 200 according to one embodiment of the present invention.

Referring to FIG. 9, the base station 200 can comprise an antenna 210, a base station AMC controller 220, a reverse AMC means 230, an AMC means 240. If the antenna 210 receives a signal, the base station AMC controller 220 extracts modulating and coding information by using a table mapping identifier included in the signal and controls the reverse AMC means 230 and the AMC means 240 in order to process the received data corresponding to the modulating method and the coding method. The base station AMC controller 220 can further comprise an identifier extractor 221 and a table saver 223. The table saver 223 can save the table including information of modulating methods and coding methods and identifier information according to the information, the identifier extractor 221 can extract information for a modulating method and a cording method from the table saver 223 by using the table mapping identifier included in the signal

According to the determined modulating and coding method, the AMC means 240 is composed in order to modulate and encode data to be transmitted, the reverse AMC means 230 is composed in order to demodulate and decode received data.

The reverse AMC means 230 can comprise a demodulator 231 for demodulating the received data, a de-interleaver 233 for de-interleaving the demodulated data, and a decoder for decoding the de-interleaved data.

And the AMC means 240 can comprise a modulator 245 for modulating data to be transmitted to the terminal 100, an interleaver 243 for interleaving the modulated data, and an encoder for encoding the interleaved data.

Description for other compositions of the base station 200, for example a transmitter, a receiver, an input, an output, a power and the like is omitted for convenience.

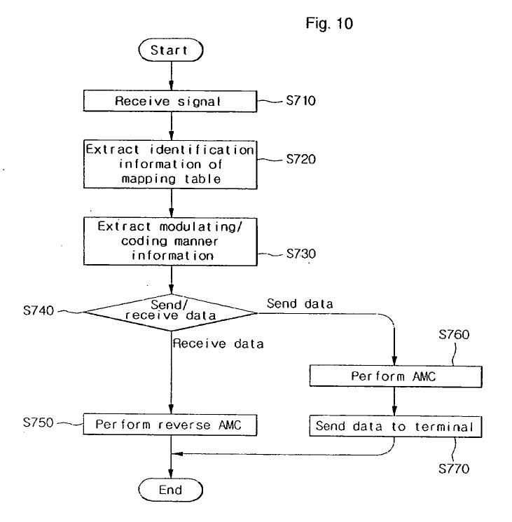

FIG. 10 is a flowchart illustrating the operation of the base station 200 according to one embodiment of the present invention.

First, in step S700 if the base station 200 receives a signal from the terminal 100, in step S710 it extracts identification information of the modulating and coding method included in the signal and in step S730 extracts a modulating and coding method corresponding to the identification information of the modulating and coding method by using the pre-saved mapping table. Here, the mapping table is identical with the mapping table saved in the terminal 100, and can be periodically updated and managed identically with the terminal 100.

In step S740 the base station 200 determines whether it sends or receives data. If it receives data, in step S750 the base station 200 can perform demodulating and decoding corresponding to the modulating and coding method corresponding the identifying information. On the other hand, if it sends data, in step S760 the base station 200 performs modulating and encoding corresponding to the modulating and coding method and then in step S770 can send to the terminal 100 the data that modulated and encoded.

The method according to one embodiment of the present invention as described above can be stored in a record medium (for example, CD-Rom, Ram, Rom, Floppy disk, hard-disk, magneto-optical disc, etc.) that is possible to be read with a computer by being embodied with program.

As described above, embodiments of the present invention provide increased up-link performance which is able to improve stably capacity and efficiency of a system irrespective of any external interference by applying with variable digital modulations and coding methods in the up-link portion corresponding to wireless channel environment.

Further, one embodiment of the present invention may improve not only forward link capacity and performance in the down-link, but also up-link performance and transmission rate. Namely, one embodiment of the present invention removes or reduces load with the feedback process of channel state information creates overhead associated with the conventional AMC method. One embodiment of the present invention further maintains a bit error rate (BER) required for the wireless system where up-link is frequent like RFID data transmission, and improves a data transmission rate of the up-link. Namely, one embodiment of the present invention is able to improve data transmission rate of the up-link while maintaining a BER requested for the system, because it can choose a method for transmitting data according to channel state by using a simple AMC algorithm based on the table of the terminal side where there is almost no multi-paths and mobility during communication.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A method of adaptive modulation and coding (AMC) for improving up-link performance in a mobile terminal, being in signal communication with a base station via a network, the method comprising:
receiving, at the mobile terminal, a signal from the base station, wherein the mobile terminal stores a mapping table which lists i) modulation and coding methods corresponding to a plurality of signal-to-noise ratios (SNRs) and ii) mapping identifiers associated with each modulation and coding method;
measuring an SNR of the received signal;
obtaining a mapping identifier corresponding to the measured SNR; and
transmitting the obtained mapping identifier to the base station.

2. The method of claim 1, further comprising:
modulating and encoding, at the mobile terminal, data based on a modulation and coding method associated with the obtained mapping identifier;
combining the obtained mapping identifier with the modulated and encoded data; and
transmitting the combined data to the base station, wherein the base station stores the same mapping table and demodulates and decodes the modulated and encoded data based on the transmitted mapping identifier and the stored mapping table.

3. The method of claim 1, wherein the network is a radio frequency identification (RFID) network.

4. The method of claim 1, further comprising:
receiving the mapping table from the base station: and
storing the received mapping table in the mobile terminal.

5. A method of adaptive modulation and coding for improving up-link performance in a base station, being in signal communication with a mobile terminal via a network, the method comprising:
transmitting a signal to the mobile terminal, wherein the base station stores a mapping table which lists i) modulation and coding methods corresponding to a plurality of signal-to-noise ratios (SNRs) and ii) mapping identifiers associated with each modulation and coding method;
receiving a mapping identifier from the mobile terminal;
receiving modulated and encoded data, associated with the received mapping identifier, from the mobile terminal; and
demodulating and decoding the received data based on a demodulation and decoding method associated with the received mapping identifier.

6. The method of claim 5, wherein the mapping identifier is received separately, or along with the modulated and encoded data from the mobile terminal.

7. The method of claim 5, wherein the network is a radio frequency identification (RFID) network.

8. The method of claim 5, further comprising:
transmitting the stored mapping table to the mobile terminal so that the terminal can store the mapping table.

9. A device for adaptive modulation and coding in a mobile terminal for improving up-link performance, the device comprising:
a receiver configured to receive a signal from a base station, being in signal communication with the mobile terminal via a network;
a signal-to-noise ratio (SNR) measurer configured to measure SNR for the received signal;
a memory configured to store a mapping table which lists i) modulation and coding methods corresponding to a plurality of signal-to-noise ratios (SNRs) and ii) mapping identifiers associated with each modulation and coding method;
an identifier extractor configured to extract a mapping identifier corresponding to the measured SNR from the mapping table; and
a transmitter configured to transmit the extracted mapping identifier to the base station.

10. The device of claim 9, further comprising:
a modulator/encoder configured to modulate and encode data based on a modulation and coding method associated with the extracted mapping identifier; and
a combiner configured to combine the modulated and encoded data with the mapping identifier,
wherein the transmitter is configured to transmit the combined data to the base station, wherein the base station stores the same mapping table and demodulates and decodes the modulated and encoded data based on the transmitted mapping identifier and the stored mapping table.

11. The device of claim 9, wherein the network is a radio frequency identification (RFID) network.

12. The device of claim 9, wherein the device is configured to receive and store the mapping table in the memory.

13. A device for adaptive modulation and coding (AMC) in a base station for improving up-link performance, the device comprising:
a transmitter configured to transmit a signal to a mobile terminal via a network;
a memory configured to store a mapping table which lists i) modulation and coding methods corresponding to a plurality of signal-to-noise ratios (SNRs) and ii) mapping identifiers associated with each modulation and coding method;
a receiver configured to receive a mapping identifier and modulated and encoded data associated with the mapping identifier from the mobile terminal; and
a demodulator/decoder configured to demodulate and decode the received data based on a demodulation and decoding method associated with the received mapping identifier.

14. The device of claim 13, wherein the receiver is configured to receive the mapping identifier separately, or along with the modulated and encoded data

15. The device of claim 13, wherein the network is a radio frequency identification (RFID) network.

16. A computer readable record medium storing a method of adaptive modulation and coding in a mobile terminal, being in signal communication with a base station via a network, the method comprising:
receiving, at the mobile terminal, a signal from the base station, wherein the mobile terminal stores a mapping table which lists i) modulation and coding methods corresponding to a plurality of signal-to-noise ratios (SNRs) and ii) mapping identifiers associated with each modulation and coding method;
measuring an SNR of the received signal;
obtaining a mapping identifier corresponding to the measured SNR; and
transmitting the obtained mapping identifier to the base station.

17. The record medium of claim 16, wherein the method further comprises:
modulating and encoding, at the mobile terminal, data based on a modulation and coding method associated with the obtained mapping identifier;
combining the mapping identifier with the modulated and encoded data; and
transmitting the combined data to the base station, wherein the base station stores the same mapping table and demodulates and decodes the modulated and encoded data based on the transmitted mapping identifier and the stored mapping table.

18. The record medium of claim 16, wherein the method further comprises:
receiving the mapping table from the base station; and
storing the received mapping table in the mobile terminal.

19. A device for adaptive modulation and coding (AMC) for improving up-link performance in a mobile terminal, being in signal communication with a base station via a network, the device comprising:
means for receiving, at the mobile terminal, a signal from the base station, wherein the mobile terminal stores a mapping table which lists i) modulation and coding methods corresponding to a plurality of signal-to-noise ratios (SNRs) and ii) mapping identifiers associated with each modulation and coding method;
means for measuring an SNR of the received signal;
means for obtaining a mapping identifier corresponding to the measured SNR; and
means for transmitting the obtained mapping identifier to the base station
